(19) United States
(12) Patent Application Publication
(10) Pub. No.: US 2009/0189246 A1
(43) Pub. Date: Jul. 30, 2009

(54) METHOD OF FORMING TRENCH ISOLATION STRUCTURES AND SEMICONDUCTOR DEVICE PRODUCED THEREBY

(76) Inventors: Hsiao-Che WU, Jhongli (TW); Ming-Yen LI, Fongshan (TW); Wen-Li TSAI, Kaohsiung County (TW)

Correspondence Address: HOLLAND & KNIGHT LLP, 10 ST. JAMES AVENUE, BOSTON, MA, 02116-3889, US

(21) Appl. No.: 12/178,154

(22) Filed: Jul. 23, 2008

(30) Foreign Application Priority Data
Jan. 30, 2008 (TW) 097103454

(51) Int. Cl. H01L 21/762; H01L 23/58

(52) U.S. Cl. 257/510; 438/435; 257/E21.546; 257/E23.002

(57) ABSTRACT

A method for forming a trench isolation structure and a semiconductor device are provided. The method comprises the following steps: forming a patterned mask on a semiconductor substrate; defining a trench with a predetermined depth D by using the patterned mask, wherein the trench has a bottom and a side wall; forming a liner layer covering the bottom and the side wall of the trench; substantially filling the trench with a flowable oxide from the bottom to a thickness d1 to form an oxide layer; forming a barrier layer with a thickness d′ to cover and completely seal the surface of the oxide layer, wherein d′<d1 and d1+d′≦1/2D; forming an insulating layer to fill the trench; and conducting a planarization process wherein the patterned mask is used as a stop layer. In the semiconductor substrate, the oxide layer, essentially composed of the flowable oxide, is confined in an isolated region. As a result, the quality of the semiconductor device manufactured by the subsequent processes on the substrate due to the diffusion of the dopants contained in the oxide layer will remain unaffected.

### RELATED APPLICATION

This application claims priority to Taiwan Patent Application No. 097103454 filed on 30 Jan. 2008.

### BACKGROUND OF THE INVENTION

1. Field of the Invention

The present invention provides a method for forming a trench isolation structure and a semiconductor device with a trench isolation structure produced thereby. In particular, the present invention provides a shallow trench isolation (STI) process using a flowable oxide for filling the trench and a semiconductor device with a shallow trench isolation structure.

2. Descriptions of the Related Art

In conventional local oxidation of silicon (LOCOS), a bird's beak effect may occur during the isolation process of integrated circuits (IC), thereby significantly influencing the subsequent manufacturing processes of transistors and contact windows. Because semiconductor devices are becoming smaller, the LOCOS technique is insufficient enough to meet the requirements for manufacturing products with high integration.

Recently, because STI processes can prevent the bird's beak effect that occurs from using the conventional LOCOS method, it has gradually replaced the LOCOS technique and has become the mainstream transistor isolation process. As implied by the term, the STI process includes steps of a photolithographic process to form a trench and the deposition of an insulating material to fill the trench. Several manners for trench filling have been proposed, for example, depositing an insulating layer by using chemical vapor deposition (CVD) and adopting trench filling materials, such as spin-on dielectric or flowable oxide.

During the initial stage of the STI process development, the CVD is always used, such as low pressure CVD (LPCVD), atmosphere pressure CVD (APCVD), or high density plasma CVD (HDPCVD) for trench filling. However, there are many operating conditions to be considered when filling the trench using the CVD. For example, although the HDPCVD is good for trench filling, the HDPCVD is very time-consuming when the aspect ratio of the trench is increasing in response to the requirement of high integration.

As for the SOD technique, it is useful for filling the trenches with a complicated pattern, but the density of the filling insulating material is lower, and thus adverse for insulation. Therefore, flowable oxides, such as boron phosphorus silicon glass (BPSG), have been used for STI trench filling. Nonetheless, since the flowable oxide must contain dopants to exhibit the flowable property after being heated, it is very possible for the dopants to diffuse during the subsequent manufacturing process of the transistors, especially when manufacturing recess gates. Unfortunately, this diffusion contaminates the substrate and reduces the yield and quality of the product elements.

In view of the above problems, the present invention provides a method for forming a trench isolation structure. Not only does the method efficiently fill a trench with a high aspect ratio, but it also prevents undesired dopant diffusion. The method provides a trench isolations structure with a good filling effect.

### SUMMARY OF THE INVENTION

The primary objective of this invention is to provide a method for forming a trench isolation structure, comprising the following steps:

forming a patterned mask on a semiconductor substrate;

defining a trench with a predetermined depth D by using the patterned mask, wherein the trench has a bottom and a side wall;

forming a liner layer covering the bottom and the side wall of the trench;

substantially filling the trench with a flowable oxide from the bottom to a thickness d1 to form an oxide layer;

forming a barrier layer with a thickness d′ to cover the surface of the oxide layer and completely seal the oxide layer, wherein d′<d1 and d1+d′≦1/2D;

forming an insulating layer to fill the trench; and

conducting a planarization process wherein the patterned mask is used as a stop layer.

Another objective of this invention is to provide a semiconductor device comprising the following components: a semiconductor substrate and a plurality of isolation trenches located in the semiconductor substrates, wherein each trench has a depth D much greater than its diameter and a liner layer covering an inside of the trench. The material filled in the trench comprises the following components:

an oxide layer, with a thickness d1, essentially composed of a flowable oxide and disposed on the liner on the bottom of the trench to substantially fill the bottom;

a barrier with a thickness d′ disposed on the oxide layer to completely seal the oxide layer, wherein d′<d1 and d1+d′≦1/2D; and

an insulating layer that is disposed on the barrier layer and fills the trench.

After reviewing the drawings and the embodiments described below, persons having ordinary skill in the art can easily understand the basic spirit of the present invention and other inventive objectives, as well as, the technical means and preferred embodiments of the claimed invention.

### BRIEF DESCRIPTION OF THE DRAWINGS

FIG. 1 depicts the steps of etching a trench and forming a liner layer according to the method of the present invention;

FIG. 2 depicts the step of forming an oxide layer according to the method of the present invention;

FIG. 3 depicts the step of forming a barrier layer according to the method of the present invention;

FIG. 4 depicts the step of forming an insulating layer according to the method of the present invention; and

FIG. 5 depicts a schematic drawing of the substrate of the semiconductor device according to the present invention.

### DESCRIPTION OF THE PREFERRED EMBODIMENT

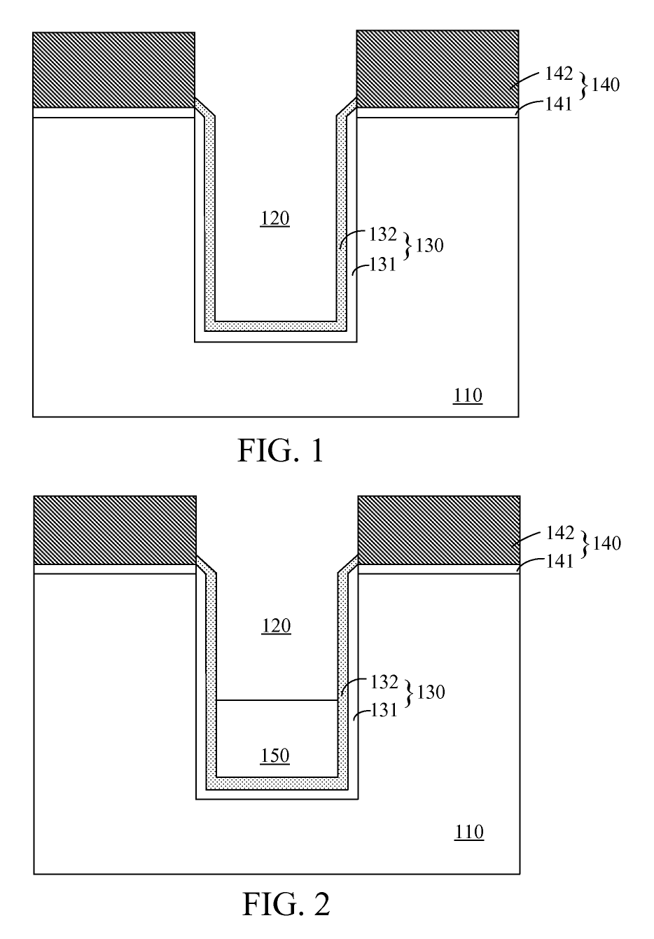

FIGS. 1 to 5 depict one embodiment of the method for forming a trench isolation structure according to the present invention. In FIG. 1, a semiconductor substrate 110 is provided. The semiconductor substrate 110 has a plurality of trenches 120 therein and a liner layer 130 covering the bottom and the side wall of the trench 120. A patterned mask 140 is formed on the surface of the semiconductor substrate 110. The patterned mask 140 can be a single layer, such as a silicon nitride layer, or a composite layer containing two or more layers, such as a combination of a silicon nitride layer and a silicon oxide layer.

The patterned mask 140 can be made by using a photolithographic process, of which the relevant techniques involved therein are well known by persons having ordinary skill in the art. As shown in FIG. 1, the semiconductor substrate 110 can be subjected to a heat treatment to form a silicon oxide pad layer 141 with a thickness of about 10 nm and then a silicon nitride pad layer 142 with a thickness ranging from about 100 nm to about 200 nm on the silicon oxide pad layer 140. Thereafter, the patterned mask 140, composed of the silicon oxide pad layer 141 and silicon nitride pad layer 142, is formed via a common photolithographic process. The silicon oxide pad layer 141 can prevent the peeling between the silicon nitride pad layer 142 and the semiconductor substrate 110 due to the poor adhesion when only the silicon nitride pad layer 142 is formed.

Then, the semiconductor substrate 110 is subjected to an etching step, such as dry etching, to form a trench 120 with a depth D in the semiconductor substrate 110 through the patterned mask 140. The diameter of the trench 120 is much smaller than its depth D. The depth D of the trench 120 is at least two times, preferably three times, and most preferably four times the diameter of the trench 120.

The liner layer 130 can also be either a single layer or a composite layer containing two or more layers. As depicted in FIG. 1, the liner layer 130 is composed of a silicon oxide liner layer 131 and a silicon nitride liner layer 132. For example, the semiconductor substrate 110 with the patterned mask 140 is subjected to a heat treatment, e.g., placed in a high temperature oven, to conduct the oxidization at the side wall and the bottom of the trench 120, thereby forming a silicon oxide liner layer 131 thereon. The silicon oxide liner layer 131 can fix the damage on the side wall and bottom of the trench 120 generated due to the etching step. After that, the silicon nitride liner layer 132 is formed on the silicon oxide liner layer 131 using low pressure chemical vapor deposition (LPCVD). The liner layer 130 can prevent defects in the semiconductor substrate 110 from occurring in the subsequent trench filling process. In addition, the liner layer 130 can also prevent the diffusion of dopants contained in the insulating material, which is deposited subsequently, into the semiconductor substrate 110. Moreover, the thickness of the liner layer 130 normally ranges from about 10 nm to about 40 nm. The thickness of the silicon nitride liner layer 132 normally ranges from about 2 nm to about 10 nm, preferably about 3 nm to 5 nm.

Thereafter, an oxide layer 150 with a thickness d1 is formed in the trench 120. The height of the surface of the oxide layer 150 is lower than that of the semiconductor substrate 110 as depicted in FIG. 2. For instance, the oxide layer 150 can be formed in the trench 120 through the following operations: depositing a flowable oxide in the trench 120; conducting an annealing step at a temperature ranging from about 800° C. to about 1200° C. to thermally treat the flowable oxide; and optionally etching the flowable oxide back to the desired depth to form the oxide layer 150.

Generally, the flowable oxide is deposited using chemical vapor deposition (CVD) such as PECVD or APCVD. The flowable oxide is normally selected from a group consisting of, but not limited to, boron-doped silicon oxide, phosphorus-doped silicon oxide, boron phosphorus silicon glass (BPSG), phosphorus silicon glass (PSG), fluorinated silicate glass (FSG), and combinations thereof. For instant, the BPSG is deposited to fill the trench 120 and cover the whole semiconductor substrate 110, and then, the semiconductor substrate 110 deposited with BPSG is placed in a furnace tube at a temperature ranging from about 850° C. to about 950° C. for a time period, typically ranging from about 20 minutes to about 40 minutes, for conducting the annealing step. The BPSG is flowable due to the high temperature to enhance the flatness of the BPSG layer and also eliminate the intra-layer pores possibly formed during the BPSG deposition to increase its density. At last, the BPSG is etched back to form the oxide layer 150 using dry etching or dry etching in combination with wet etching. The back etching depth depends on many conditions. For example, the back etching is conducted until the height of the oxide layer 150 is lower than the burying depth of the recess gate that will be manufactured subsequently or until the subsequent insulating layer can completely fill the trench. In general, the back etching process is conducted to attain a depth of half the depth D of the trench 120 or less, as shown in FIG. 2. Furthermore, the BPSG can be used to just fill the portion of half the depth D of the trench 120 or less, and then an annealing step is conducted to enhance the flowability of BPSG to provide a flat oxide layer 150 without using a back etching step.

As shown in FIG. 3, after the deposition of the oxide layer 150, a barrier layer 160 with a thickness d′ is formed in the trench 120 to cover and completely seal the oxide layer 150. The thickness d′ of the barrier layer 160 normally ranges from about 2 nm to about 10 nm, preferably about 3 nm to about 5 nm, and is thinner than the thickness d1 of the oxide layer 150. The total thickness of d′ and d1 is thinner than or equal to the half of the depth D of the trench 120. Preferably, the silicon nitride layer is deposited as the barrier layer 160 using a process such as LPCVD. As shown in FIG. 3, since the oxide layer 150 is surrounded by the barrier layer 160 and the liner layer 130 and confined in an isolated region, and thus, it can efficiently prevent the diffusion of the dopants, such as B or P, contained in the oxide layer 150. As a result, the quality of the semiconductor substrate 110 is not decreased, nor are the subsequent processes, such as the manufacturing process of the recess gate, adversely affected.

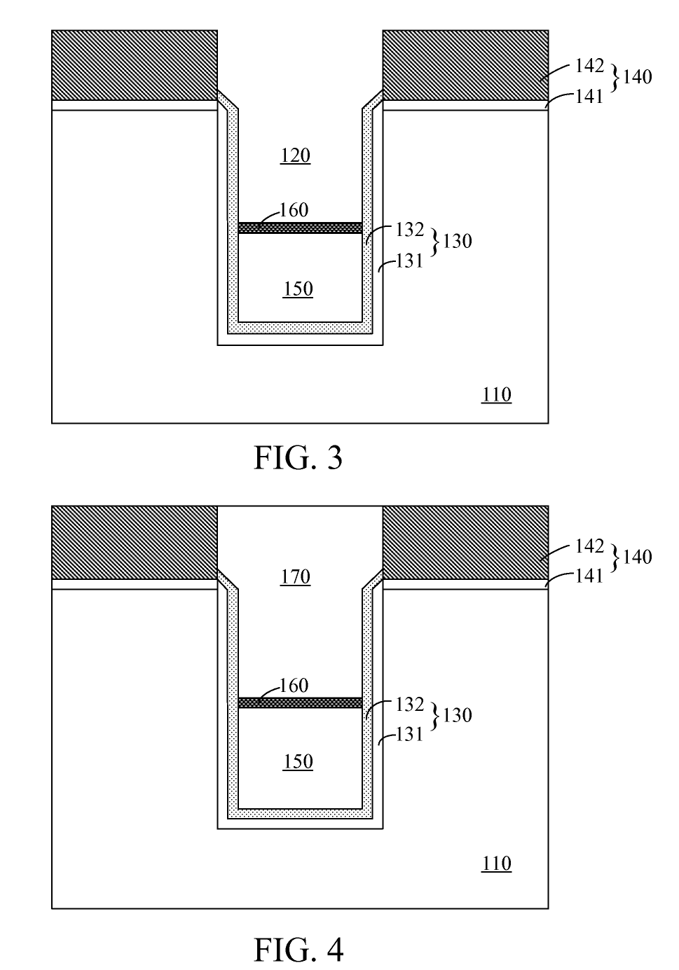

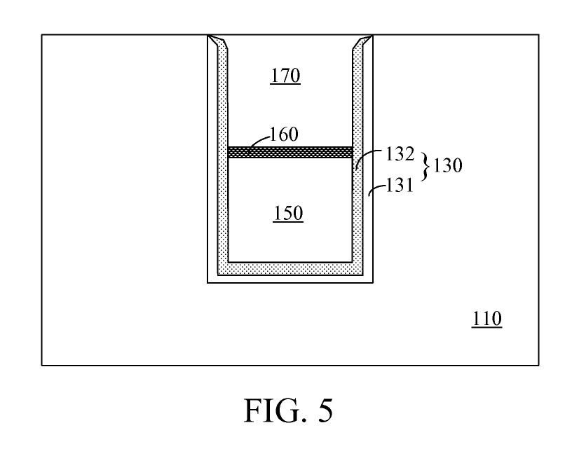

As shown in FIG. 4, an insulating layer 170 is formed to cover the semiconductor substrate 110 and fill the trench 120. According to one embodiment of the process of the present invention, the chemical vapor deposition such as the high density plasma chemical vapor deposition (HDPCVD) can be used. The material of the insulating layer 170 can be any STI insulating materials well known by persons skilled in the art, such as silicon oxide. As shown in FIG. 5, a chemical mechanical polishing is conducted and the patterned mask 140 is used as the polishing stop layer. In particular, the silicon nitride pad layer 142 is used as the polishing stop layer. Then, the patterned mask 140, composed of the silicon nitride pad layer 142 and the silicon oxide pad layer 141, is completely removed using such as wet etching without damaging the surface of the semiconductor substrate 110. The aforesaid step normally utilizes hot phosphoric acid to further remove the silicon oxide pad layer 141 to accomplish the trench isolation structure shown in FIG. 5. The trench isolation structure can be an especially shallow trench isolation structure with a high aspect ratio, which is suitable for the current semiconductor devices that need a high integration.

Therefore, the present invention also provides a semiconductor device prepared by the above method, comprising a semiconductor substrate and a plurality of trenches located therein. Each trench has a depth D much greater than its diameter, has a liner layer covering an inside thereof, and is filled with an insulating material.

The trench isolation structure shown in FIG. 5 is illustrated to describe the semiconductor substrate 110 of the semiconductor device of the present invention. For the sake of simplicity, FIG. 5 only depicts one trench for illustration. As shown in FIG. 5, the semiconductor substrate 110 comprises a trench 120 and a continuous liner layer 130 on the bottom and the side wall of the trench 120. Also, the inside of the trench 120 has an oxide layer 150 with a thickness d1, which is disposed on the liner layer 130 on its bottom to substantially fill the bottom. The inside of the trench 120 also has a barrier layer 160 with a thickness d′ disposed on the oxide layer 150 to completely seal the oxide layer 150, wherein d′<d1 and d1+d′≦1/2D. Besides, an insulating layer 170 is disposed on the barrier layer 160 and fills the trench 120. According to the present invention, the insulating layer filling the trench 120 is composed of the oxide layer 150, the barrier layer 160, and the insulating layer 170, which are used in combination for isolating the transistors from each other of the IC substrate.

The materials and relevant manufacturing processes of the liner layer 130, the oxide layer 150, the barrier layer 160, and the insulating layer 170 are mentioned above and will not be in detail described herein. According to the present invention, the oxide layer 150 should be composed of BPSG, while the barrier layer 160 should be a silicon nitride layer. The insulating layer 170 is a silicon oxide layer formed by the HDPCVD. Moreover, when the flowable oxide such as BPSG is used as the first insulating layer, i.e., the oxide layer 150, it is advantageous to fill the trench with a high aspect ratio and prevent the formation of pores. Meanwhile, the barrier layer 160 can prevent the diffusion of the dopants contained in the BPSG. Then, an oxide layer is deposited in the portion of the trench that will be filled with a lower aspect ratio using HDPCVD to achieve the semiconductor substrate of the present invention.

Given the above, the present invention forms the barrier layer 160 during the filling of the trench 120. The combination of the barrier layer 160 with the liner layer 130 disposed on the bottom and the side wall of the trench 120 can confine the material forming the oxide layer 150, such as BPSG containing B and P, in an isolated region, thus preventing the diffusion of the dopants e.g., B and P to enhance the process quality and yield of the semiconductor substrates.

What is claimed is:

1. A method for forming a trench isolation structure comprising:
forming a patterned mask on a semiconductor substrate;
defining a trench with a predetermined depth D by using the patterned mask, wherein the trench has a bottom and a side wall;
forming a liner layer covering the bottom and the side wall of the trench;
substantially filling the trench with a flowable oxide from the bottom to a thickness d1 to form an oxide layer;
forming a barrier layer with a thickness d′ to cover the surface of the oxide layer and completely seal the oxide layer, wherein d′<d1 and d1+d′≦1/2D;
forming an insulating layer to fill the trench; and
conducting a planarization process wherein the patterned mask is used as a stop layer.

2. The method of claim 1, further comprising an annealing step before forming the barrier layer.

3. The method of claim 1, wherein the liner layer comprises a silicon nitride layer.

4. The method of claim 1, wherein the flowable oxide is boron phosphorus silicon glass (BPSG).

5. The method of claim 2, wherein the annealing step is conducted at a temperature ranging from about 800° C. to about 1200° C.

6. The method of claim 1, wherein the barrier layer is a silicon nitride layer.

7. The method of claim 1, wherein the thickness d′ of the barrier layer is about 2 nm to about 10 nm.

8. A semiconductor device comprising:
a semiconductor substrate; and
a plurality of isolation trenches located in the semiconductor substrate, wherein each trench has a depth D much greater than its diameter and a liner layer covering an inside of the trench, and the material filled in the trench comprises:
an oxide layer, with a thickness d1, essentially composed of a flowable oxide and disposed on the liner layer on the bottom of the trench to substantially fill the bottom;
a barrier layer with a thickness d′ disposed on the oxide layer to completely seal the oxide layer, wherein d′<d1 and d1+d′≦1/2D; and
an insulating layer which is disposed on the barrier layer and fills the trench.

9. The device of claim 8, wherein the liner layer comprises a silicon nitride layer.

10. The device of claim 8, wherein the oxide layer is boron phosphorus silicon glass (BPSG).

11. The device of claim 8, wherein the barrier layer is a silicon nitride layer.

12. The device of claim 8, wherein the thickness d′ of the barrier layer is about 2 nm to about 10 nm.

13. The device of claim 8, wherein the liner layer is a continuous layer.

14. The device of claim 8, wherein the liner layer has a thickness ranging from about 10 nm to about 40 nm.
